(19) United States
(12) Patent Application Publication
(10) Pub. No.: US 2012/0107991 A1
(43) Pub. Date: May 3, 2012

(54) MAGNESIUM DOPING IN BARRIERS IN MULTIPLE QUANTUM WELL STRUCTURES OF III-NITRIDE-BASED LIGHT EMITTING DEVICES

(75) Inventors: Chia-Yen Huang, Goleta, CA (US); Shuji Nakamura, Santa Barbara, CA (US); Steven P. DenBaars, Goleta, CA (US); James S. Speck, Goleta, CA (US)

(73) Assignee: THE REGENTS OF THE UNIVERSITY OF CALIFORNIA, Oakland, CA (US)

(21) Appl. No.: 13/279,121

(22) Filed: Oct. 21, 2011

Related U.S. Application Data
(60) Provisional application No. 61/405,416, filed on Oct. 21, 2010.

(51) Int. Cl. H01L 33/06; H01S 5/343; H01L 21/18

(52) U.S. Cl. 438/47; 257/13; 372/45.012; 257/E21.085; 257/E33.008

(57) ABSTRACT

A III-nitride-based light emitting device having a multiple quantum well (MQW) structure and a method for fabricating the device, wherein at least one barrier in the MQW structure is doped with magnesium (Mg). The Mg doping of the barrier is accomplished by introducing a bis(cyclopentadienyl)magnesium (Cp₂Mg) flow during growth of the barrier using metalorganic chemical vapor deposition (MOCVD). The barriers of the MQW structure may be undoped, fully Mg-doped or partially Mg-doped. When the barrier is partially Mg-doped, only portions of the barrier are Mg-doped to prevent Mg diffusion into quantum wells of the MQW structure. The Mg-doped barriers preferably are high Al composition AlGaN barriers in nonpolar or semipolar devices.

### CROSS REFERENCE TO RELATED APPLICATION

This application claims the benefit under 35 U.S.C. Section 119(e) of the following co-pending and commonly-assigned application:

U.S. Provisional Patent Application Ser. No. 61/405,416, filed on Oct. 21, 2010, by Chia-Yen Huang, Shuji Nakamura, Steven P. DenBaars, and James S. Speck, entitled “MAGNESIUM DOPING IN BARRIERS IN MULTIPLE QUANTUM WELL STRUCTURES OF III-NITRIDE-BASED LIGHT EMITTING DEVICES,” attorneys' docket number 30794.395-US-P1 (2011-171-1);

which application is incorporated by reference herein.

### BACKGROUND OF THE INVENTION

1. Field of the Invention

The invention is related to the field of III-nitride-based light emitting devices.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

For long wavelength (>500 nm) emissions, light emitting diodes (LEDs) and laser diodes (LDs) have been grown on semipolar and nonpolar planes of III-nitride materials.

For example, Sumitomo Electric Industry has announced 531 nm lasing under pulse operation in semipolar, (20-21) plane, devices. In these devices, the barrier composition and doping structure are not disclosed, but the threshold voltage is high (Vth˜18 V). [1]

In another example, the University of California at Santa Barbara (UCSB), the assignee of the present invention, has announced lasing at 516 nm in an A1GaN-cladding free LD with undoped AlGaN barriers. [2]

Generally, AlGaN barriers are utilized to achieve good crystal quality for quantum wells (QWs). However, the use of AlGaN barriers requires a higher forward voltage and results in the unequal distribution of electrical carriers among the QWs, which reduces internal efficiency of the device.

What is needed, then, is an improved method of fabricating III-nitride-based light emitting devices that solves or reduces these problems. The present invention satisfies this need.

### SUMMARY OF THE INVENTION

To overcome the limitations in the prior art described above, and to overcome other limitations that will become apparent upon reading and understanding the present specification, the present invention discloses a III-nitride-based light emitting device having a multiple quantum well (MQW) structure and method for fabricating the device, wherein at least one barrier in the MQW structure is doped with magnesium (Mg).

This is accomplished by introducing a bis(cyclopentadienyl)magnesium (Cp₂Mg) flow during growth of one or more of the barriers, using metal organic chemical vapor deposition (MOCVD), in order to dope the barrier with Mg. The barriers of the MQW structure may be undoped, fully Mg-doped or partially Mg-doped. When the barrier is partially Mg-doped, only portions of the barrier are Mg-doped, to prevent Mg diffusion into quantum wells of the MQW structure.

The barrier may be a multilayer structure of different compositions or a structure with a graded composition. Preferably, the barrier has a composition comprising AlₓIn_{y}Ga_{1-x-y}N, where 0≦x≦1, 0≦y≦1, and 0≦x+y≦1, and more preferably, the Mg-doped barriers are high Al composition AlGaN barriers.

The III-nitride-based light emitting device may be a polar, nonpolar or semipolar device, such as a light emitting diode (LED), laser diode (LD) or superluminescent diode (SLD).

### BRIEF DESCRIPTION OF THE DRAWINGS

Referring now to the drawings in which like reference numbers represent corresponding parts throughout:

FIG. 1 is a schematic illustration of Mg-doping in barriers of a III-nitride-based light emitting device according to one embodiment of the present invention.

FIG. 2 shows a composition profile of triple quantum well (TQW) laser epilayers with Mg-doped and undoped barriers by secondary ion mass spectroscopy (SIMS), according to one embodiment of the present invention.

FIG. 3 is a graph of experimental data of quick test (QT) power (mW) and electroluminescence (EL) wavelength (λ_{EL}) of LD or LED eiplayers under 20 mA current injection.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention provides Mg doping in barriers of QWs to improve hole transport and carrier distribution between the QWs. In one embodiment, the Mg doping is performed on III-nitride-based light emitting devices, such as laser diodes, light-emitting diodes and superluminescence diodes, grown on semipolar or nonpolar bulk GaN substrates and having long-wavelength MQW structures in their active or light emitting regions, although the present invention is applicable to other light emitting devices as well.

Technical Description

Conventional MQW light emitting devices contain at least two QWs with intermediate barriers between wells. For devices with a long emission wavelength, the forward voltage is usually higher as compared to devices with a short emission wavelength.

The present invention introduces a Cp₂Mg flow during growth of one or more of the barriers using MOCVD, resulting in Mg-doped barriers, in order to reduce the forward voltage and to increase the output power of the device. Preferably, the Mg-doped barriers are high Al composition (approximately 5 to 10% Al composition) AlGaN barriers on nonpolar or semipolar devices.

The barrier may be fully or partially Mg-doped. Partial Mg doping is performed to reduce possible Mg diffusion from the barrier into the QWs. In this regard, some percentage of the barrier, such as the first and/or last 10 to 15% of the barrier, can be grown without Mg doping. Of course, other percentages may be used as well without departing from the scope of the present invention.

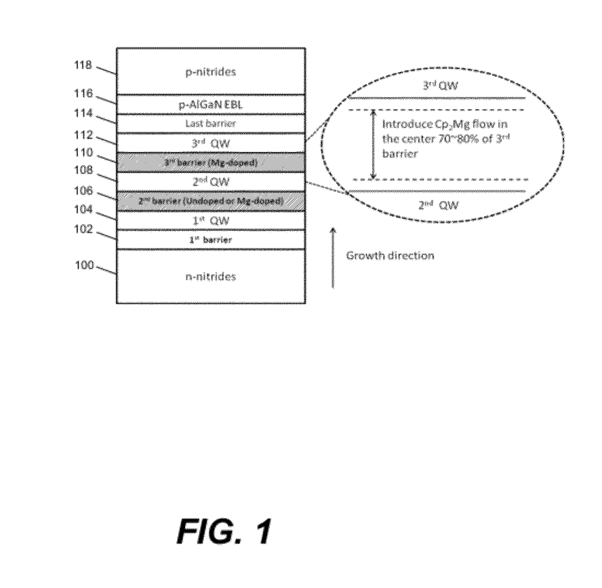

FIG. 1 is a schematic illustration of Mg-doping in barriers of a III-nitride-based light emitting device according to one embodiment of the present invention. The arrow in FIG. 1 indicates the growth direction from bottom to top. The III-nitride-based light emitting device includes one or more n-nitrides 100 (e.g., one or more n-type III-nitride layers on a substrate or template, wherein the n-type III-nitride layers may include an n-type contact layer, an n-type separate confinement heterostructure (SCH) cladding layer, etc.), a 1^{st} barrier 102, a 1^{st} QW 104, a 2^{nd} barrier 106 (which may be undoped, fully Mg-doped or partially Mg-doped), a 2^{nd} QW 108, a 3^{rd} barrier 110 (which is Mg-doped), a 3^{rd} QW 112, a last barrier 114, a p-type AlGaN electron blocking layer (EBL) 116 and one or more p-nitrides 118 (e.g., one or more p-type III-nitride layers, wherein the p-type III-nitride layers may include a p-type SCH cladding layer, a p-type contact layer, etc.).

The inset of FIG. 1 shows that the 3^{rd} barrier 110, when Mg-doped, may be only partially Mg-doped across the thickness of the barrier. For example, when partially Mg-doped, the Cp₂Mg flow may be introduced only during the growth of the center 70-80% portion of the barrier 110, or alternatively, there is no Cp₂Mg flow during the growth of the initial 10-15% portion of the barrier 110 and during the growth of the final 10-15% portion of the barrier 110. In another example, a partially Mg-doped barrier may have a graded composition, wherein the Mg-doping changes across the thickness of the barrier.

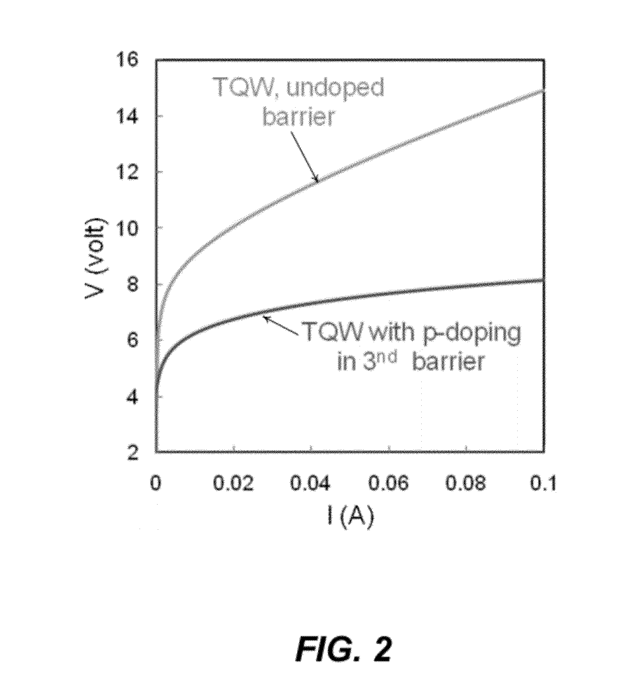

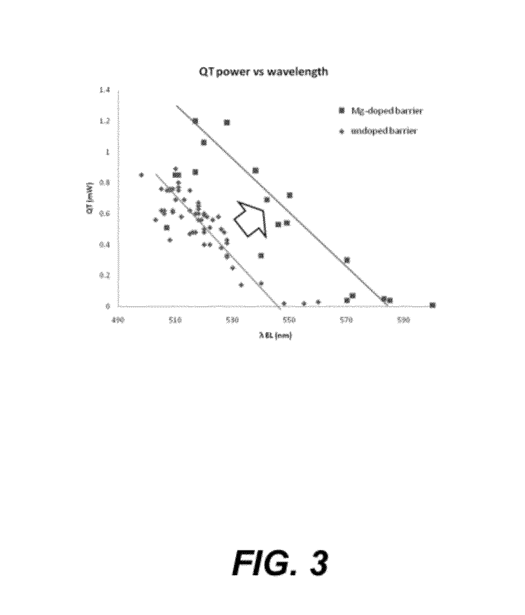

FIG. 2 is a graph of the current-voltage (I-V) characteristics of a triple quantum well (TQW) laser structure with an undoped 3^{rd} barrier and a TQW laser structure with a p-doped 3^{rd} barrier, wherein both curves have similar epilayer structures and emission wavelengths (˜520 nm under 20 mA). FIG. 3 is a graph of experimental data of quick test (QT) power (mW) and electroluminescence (EL) wavelength (λ_{EL}) of LD or LED eiplayers under 20 mA current injection, wherein the data points represented by squares are for at least one barrier doped with Mg, and the data points represented by diamonds are for barriers that are undoped. Lines are fit for each set of data points, and the arrow shows the increase in power at longer wavelengths for Mg-doped barriers as compared to undoped barriers

Advantages and Improvements The present invention provides a number of advantages and improvements. For example, the present invention reduces the forward voltage of laser epitaxy up to about 3-5 Volts with further optimization. The improved carrier transport due to this invention will enable companies to extend the boundary of lasing wavelength more than about 10 nm with proper epitaxy design of nitride-based LDs. Finally, bright MQW yellow or red LEDs grown on bulk GaN substrate are also achievable with this invention.

Possible Modifications and Variations

Although described above in the context of nonpolar and semipolar III-nitrides, the present invention can be also applied to devices on polar (c-plane) III-nitrides for improving hole transport.

Variations of the barrier structure can include GaN barriers, InGaN barriers, quaternary AlInGaN barriers, graded AlGaN barriers, GaN/AlGaN step barriers and GaN/AlGaN/GaN step barriers, etc., for different purposes.

Doping profiles in the barriers could be further studied for optimization of internal efficiency and device reliability.

Nomenclature The terms “III-nitride,” “Group-III nitride”, or “nitrides,” as used herein refer to any alloy composition of the (Ga, Al, In, B)N semiconductors having the formula Ga_{w}AlₓIn_{y}B_{z}N where 0≦w≦1, 0≦x≦1, 0≦y≦1, 0≦z≦1, and w+x +y+z=1. These terms are intended to be broadly construed to include respective nitrides of the single species, Ga, Al, In and B, as well as binary, ternary and quaternary compositions of such Group III metal species. Accordingly, it will be appreciated that the discussion of the invention hereinafter in reference to GaN and InGaN materials is applicable to the formation of various other (Ga, Al, In, B)N material species. Further, (Ga, Al, In, B)N materials within the scope of the invention may further include minor quantities of dopants and/or other impurity or inclusional materials.

Many (Ga, Al, In, B)N devices are grown along the polar (0001) c-plane of the crystal, although this results in an undesirable quantum-confined Stark effect (QCSE), due to the existence of strong piezoelectric and spontaneous polarizations. One approach to decreasing polarization effects in (Ga, Al, In, B)N devices is to grow the devices on nonpolar or semipolar planes of the crystal.

The term “nonpolar plane” includes the {11-20} planes, known collectively as a-planes, and the {10-10} planes, known collectively as m-planes. Such planes contain equal numbers of gallium and nitrogen atoms per plane and are charge-neutral. Subsequent nonpolar layers are equivalent to one another, so the bulk crystal will not be polarized along the growth direction.

The term “semipolar plane” can be used to refer to any plane that cannot be classified as c-plane, a-plane, or m-plane. In crystallographic terms, a semipolar plane would be any plane that has at least two nonzero h, i, or k Miller indices and a nonzero l Miller index, which includes {20-21}, {11-22}, {10-11}, {10-13}, {10-12} and {10-14}. Generally, semipolar planes of wurtzite crystals include {n, 0, −n, m}, {n, 0, −n, −m}, {n, m, −n−m, l} and {n, m, −n−m, −l}, etc., wherein n, m and l are integers. Subsequent semipolar layers are equivalent to one another, so the crystal will have reduced polarization along the growth direction.

Miller indices are a notation system in crystallography for planes and directions in crystal lattices, wherein the notation {h, i, k, l} denotes the set of all planes that are equivalent to (h, i, k, l) by the symmetry of the lattice. The use of braces, { }, denotes a family of symmetry-equivalent planes represented by parentheses, ( ) wherein all planes within a family are equivalent for the purposes of this invention.

### REFERENCES

The following references are incorporated by reference herein:

1. Enya et. al., Appl. Phys. Express 2 (2009).

2. You-Da Lin et. al., Appl. Phys. Express, 3, (2010).

### Conclusion

This concludes the description of the preferred embodiments of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method for fabricating an optoelectronic device, comprising:
fabricating a III-nitride-based light emitting device having a multiple quantum well (MQW) structure, wherein at least one barrier in the MQW structure is doped with magnesium (Mg).

2. The method of claim 1, wherein the fabricating step further comprises introducing a bis(cyclopentadienyl)magnesium (Cp₂Mg) flow during growth of one or more of the barriers, in order to dope the barrier with Mg.

3. The method of claim 2, wherein the growth is performed using metal organic chemical vapor deposition (MOCVD).

4. The method of claim 1, wherein the barrier is fully Mg-doped.

5. The method of claim 1, wherein the barrier is partially Mg-doped, such that only portions of the barrier are Mg-doped, to prevent Mg diffusion into quantum wells of the MQW structure.

6. The method of claim 1, wherein the barrier is a multilayer structure of different compositions or a structure with a graded composition.

7. The method of claim 6, wherein the barrier has a composition comprising AlₓIn_{y}Ga_{1-x-y}N, where 0≦x≦1, 0≦y≦1, and 0≦x+y≦1.

8. The method of claim 1, wherein the III-nitride-based light emitting device is a polar, nonpolar or semipolar device.

9. The method of claim 1, wherein the III-nitride-based light emitting device is a light emitting diode (LED), laser diode (LD) or superluminescent diode (SLD).

10. A device fabricated using the method of claim 1.

11. An optoelectronic device, comprising:
a III-nitride-based light emitting device having a multiple quantum well (MQW) structure, wherein at least one barrier in the MQW structure is doped with magnesium (Mg).

12. The device of claim 11, wherein a bis(cyclopentadienyl)magnesium (Cp₂Mg) flow is introduced during growth of one or more of the barriers, in order to dope the barrier with Mg.

13. The device of claim 12, wherein the growth is performed using metal organic chemical vapor deposition (MOCVD).

14. The device of claim 11, wherein the barrier is fully Mg-doped.

15. The device of claim 11, wherein the barrier is partially Mg-doped, such that only portions of the barrier are Mg-doped, to prevent Mg diffusion into quantum wells of the MQW structure.

16. The device of claim 11, wherein the barrier is a multilayer structure of different compositions or a structure with a graded composition.

17. The device of claim 16, wherein the barrier has a composition comprising AlₓIn_{y}Ga_{1-x-y}N, where 0≦x≦1, 0≦y≦1, and 0≦x+y≦1.

18. The device of claim 11, wherein the III-nitride-based light emitting device is a polar, nonpolar or semipolar device.

19. The device of claim 11, wherein the III-nitride-based light emitting device is a light emitting diode (LED), laser diode (LD) or superluminescent diode (SLD).
